(19) United States
(12) Patent Application Publication
(10) Pub. No.: US 2021/0313197 A1
(43) Pub. Date: Oct. 7, 2021

(54) METHOD FOR MANUFACTURING CONDUCTIVE PILLAR USING CONDUCTIVE PASTE

(71) Applicant: DIC Corporation, Tokyo (JP)

(72) Inventors: Ryota Yamaguchi, Sakura-shi (JP); Yasuhiro Sente, Sakura-shi (JP); Makoto Yada, Sakura-shi (JP)

(73) Assignee: DIC Corporation, Tokyo (JP)

(21) Appl. No.: 17/262,067

(22) PCT Filed: Apr. 25, 2019
(86) PCT No.: PCT/JP2019/017604

§ 371 Date: Jan. 21, 2021

(30) Foreign Application Priority Data
Jul. 26, 2018 (JP) 2018-140211

(51) Int. Cl. H01L 21/48; H01L 23/00; B41M 3/00; B41M 1/12

(52) U.S. Cl. CPC H01L 21/4867; H01L 24/11; H01L 23/49811; B41M 1/12; B41M 3/006

(57) ABSTRACT

An electroplating method that is a conventional method has had a problem that it is difficult to manufacture fine pillars without being affected by an undercut. Furthermore, an electroless plating method has had a problem that it is difficult to manufacture pillars having the same shape without any void. The inventors have performed intensive investigations to solve the above problems and, as a result, have found that fine conductive pillars with a high aspect ratio can be readily manufactured on a substrate having an electrode section in such a manner that after a conductive paste containing metal micro-particles is applied in a reduced pressure state, the conductive paste is exposed to standard pressure. The present invention has a particular effect on the manufacture of a metal pillar that is a terminal for flip-chip mounting.

### TECHNICAL FIELD

The present invention relates to a method for manufacturing a conductive pillar or conductive post that is a terminal for flip-chip mounting, which is a technique for connecting a semiconductor chip to a package interposer in a semiconductor package. The manufacturing method according to the present invention is characterized by using a conductive paste containing moral micro-particles.

### BACKGROUND ART

A semiconductor device is manufactured in such a manner that an electronic circuit is manufactured on a semiconductor chip and electrodes on the semiconductor chip are connected to electrodes on a semiconductor package. Hitherto, electrodes on a semiconductor chip have been electrically connected to electrodes on a semiconductor package by using boding wires made of gold or copper. A flip-chip method is used to electrically connect a semiconductor chip to a semiconductor package. Gold bumps and solder bumps are used as a typical connection measure in the flip-chip method.

However, a flip-chip mounting technique using conductive pillars is recently attracting attention because of the higher integration of chips in recent years. The conductive pillars are manufactured on a semiconductor chip and the tip of each pillar is connected to an electrode of a semiconductor package, conductive pillars generally used are those having a pillar diameter of 70 μm or less and a pillar height of 50 μm to 60 μm.

Various metal species (various metals such as gold, solder, and copper; alloys; and the like) can be used in conductive pillars. When a metal species used is gold or copper, the metal species has lower electrical resistance as compared to solder and therefore can respond to a large current. The conductive pillars can suppress the supply of solder as compared to solder bumps. Therefore, the conductive pillars enable the reduction of bump pitch and can cope with high integration. In addition, the conductive pillars can maintain the same sectional area from electrodes on a semiconductor chip to electrodes on a semiconductor package and therefore have an advantage that the conductive pillars can respond to a large current.

The manufacture of the conductive pillars is important in semiconductor packaging because of the above reasons. A method for simply manufacturing a conductive pillar in high yield is desired.

A method in which a plating technique is used i3 known as a method for manufacturing a conductive pillar on a substrate.

Patent Literatures 1 and 2 disclose a method in which a plating layer called a seed layer is prepared on an electrode pad and a conductive pillar (copper pillar) made of copper is manufactured by electroplating. However, in a case where a conductive pillar is manufactured by plating, a seed layer is provided on an entire surface and therefore a step of removing a patterned resist layer and the seed layer after the manufacture of the pillar is necessary. A step of removing a seed layer by etching causes an undercut in a copper pillar (Patent Literature 3). Thus, there is a problem in that it is difficult to manufacture a fine conductive pillar by a plating method.

Furthermore, a method in which electroless plating is used is known as a method for manufacturing a conductive pillar by a plating technique. This method is as follows: a photoresist layer is made on a semiconductor chip, an opening is formed in a portion of the photoresist layer that is used to manufacture the conductive pillar, a copper pillar is manufactured in an opening portion by electroless plating, and a solder-plated layer is manufactured on the top of the copper pillar. However, in order to manufacture a conductive pillar with a large height-to-diameter ratio (aspect ratio), that is, a long and narrow conductive pillar by an electroless plating method, plating needs to be grown in a deep hole with a small diameter. In this case, a plating solution with sufficient concentration needs to be continuously fed to an opening portion, the growth of the conductive pillar is slow, and throughput is poor. As a result, the following problems occur: a problem that the diameter of the conductive pillar is loss than a target value, a problem that the shape thereof is unstable, a problem that a void occurs in precipitated metal, and the like. There is a problem in that these problems cause reductions in quality and reproducibility (Patent Literature 4).

In addition, a plating method needs to recycle or dispose of a large amount of liquid waste, has a large environmental impact, and requires costs for equipment maintenance. Therefore, an alternative measure is desired.

A method for manufacturing a pillar by filling an opening portion of a resist layer patterned in advance with a conductive paste by using a squeegee or the like can be conceived as an alternative to the plating method. However, when the diameter of a conductive pillar is small due to high-density or high-integration semiconductor packaging, it is difficult to fill a conductive paste deep into an opening portion.

### CITATION LIST

### Patent Literature

PTL 1: Japanese Unexamined Patent Application Publication No. 2011-029636

PTL 2: Japanese Unexamined Patent Application Publication No. 2012-532459

PTL 3: Japanese Unexamined Patent Application Publication No. 2012-015396

PTL 4: WO 2016/031969

### SUMMARY OF INVENTION

### Technical Problem

Thus, an electroplating method that is a conventional method has had a problem that it is difficult to manufacture a fine conductive pillar without being affected by an undercut. Furthermore, an electroless plating method has had a problem that it is difficult to manufacture pillars having the same shape without any void.

It is required that an undercut can be prevented and conductive pillars having the same shape are provided with high reproducibility. The present invention is intended to provide a method for manufacturing a fine conductive pillar by an embedding method by using a conductive paste for pillar manufacturing.

### Solution to Problem

The inventors have performed intensive investigations to solve the above problems and, as a result, have found that a fine conductive pillar with a high aspect ratio can be readily manufactured on a substrate having an electrode section in such a manner that after a conductive paste containing metal micro-particles is applied in a reduced pressure state, the conductive paste is exposed to atmospheric pressure.

It has been found that the present invention has a particular effect on the manufacture of a conductive pillar that is a terminal for flip-chip mounting.

That is, the present invention provides

(1) a method for manufacturing a conductive pillar on a substrate having an electrode section by using a conductive paste containing metal micro-particles, the method including a first step of applying, in an atmosphere with an atmospheric pressure of 10 kPa or less, the conductive paste to a surface of a resin film having an opening portion formed on the substrate having the electrode section, a second step of returning a pressure in the atmosphere to standard pressure after applying the conductive paste and filling the conductive paste in the opening portion, and a third step of removing the conductive paste remaining on the surface of the resin film.

(2) In the method for manufacturing the conductive pillar specified in Item (1), a squeegee made of rubber or metal is used in the step of applying the conductive paste specified in Item (1) and the step of removing the conductive paste specified in Item (1).

(3) In the method for manufacturing the conductive pillar specified in Item (1), the step of applying the conductive paste specified in Item (1) is performed by screen printing.

(4) In the method for manufacturing the conductive pillar specified in any one of Items (1) to (3), the opening portion formed on the substrate having the electrode section specified in Item (1) has a diameter of 50 μm or less.

### Advantageous Effects of Invention

The present invention is a method for manufacturing a conductive pillar on a substrate having an electrode section by using a conductive paste containing metal micro-particles.

Using the present invention enables pillars to be simply manufactured in such a manner that the conductive paste is filled with a squeegee or the like in opening portions of a resist layer patterned in advance without using a plating technique that is a conventional technique.

Directly manufacturing pillars on a substrate having an electrode section by using a conductive paste enables an etching undercut that is a problem with a conventional method to be eliminated, thereby enabling fine copper pillars to be manufactured.

The manufacture of a pillar by using a conductive paste is not limited by the deterioration of a plating solution, the diffusion control of ions, or the like and therefore can probably solve problems with quality and reproducibility in an electroless plating method.

Using the present invention enables a fine conductive pillar capable of withstanding high-density or high-integration semiconductor packaging in an embedding method to be singly manufactured.

### BRIEF DESCRIPTION OF DRAWINGS

FIG. 1 is a schematic sectional view illustrating a step (first step) of manufacturing conductive pillars according to the present invention.

FIG. 2 is a schematic sectional view illustrating a step of manufacturing the conductive pillars according to the present invention.

FIG. 3 is a sectional photograph of conductive pillars prepared by a method according to the present invention.

### DESCRIPTION OF EMBODIMENTS

The present invention is described below in detail.

<Conductive Paste>

A method for producing a conductive paste, used in the present invention, containing metal micro-particles is described below in detail.

(Metal Micro-Particles)

A metal species that can be used as the metal micro-particles is not particularly limited as long as it may be chemically bended to a functional group in a protective agent below. For example, gold, silver, copper, nickel, zinc, aluminum, platinum, palladium, tin, chromium, lead, tungsten, and the like can be used. The metal species may be a single type of metal, a mixture of two or more types of metals, or an alloy.

The content of the metal micro-particles in the conductive paste is not particularly limited and is preferably in the range of 40% by mass or more to less than 95% by mass concentration because sufficient fluidity needs to be ensured in order to fill the conductive paste in an opening portion.

(Synthesis of Metal Micro-Particles)

As a method for synthesizing the metal micro-particles according to the present invention, a chemical reduction method has been used. If the surfaces of the metal micro-particles can be protected with the protective agent and the size of the metal micro-particles is 1 μm or less, an appropriate method can be used. For example, a pyrolysis method and an electrochemical method can be used as a wet method in addition to the chemical reduction method. A gas evaporation technique and a sputtering method can be used as a dry method.

(Protective Agent)

The protective agent according to the present invention can be appropriately selected from compounds containing a functional group having affinity to the metal micro-particles and a solvent. The protective agent can be used regardless of the magnitude of the molecular weight thereof. Designing the protective agent depending on a metal species used or desired physical properties enables high conductivity or dispersion stability to be imparted to the metal micro-particles.

In particular, using a protective agent containing a carboxy group, phosphate group, sulfonic acid group, or heteroaromatic group (for example, an imidazole group) exhibiting somewhat strong adsorbability for metal enables high dispersion stability to be imparted to fine particles. Alternatively, using a protective agent containing, for example, an amino group (for example, a dimethylaminoethyl group or a dimethylaminopropyl group), hydroxy group (a hydroxyethyl group or a hydroxypropyl group), or aromatic group (for example, a benzyl group) which exhibits a medium interaction with metals and which has adsorbability varying with the acidity or alkalinity of a dispersion medium enables high conductivity inducing low volume resistivity in low-temperature sintering to be imparted. Selecting a protective agent for the metal micro-particles depending on various purposes as described above enables characteristics of the metal micro-particles to be freely changed, in the case of using a protective agent with low molecular weight, using two or more types of compounds enables various characteristics to be induced. In the case of using a protective agent with high molecular weight, changing the number and type of functional groups in a compound enables various characteristics to be induced.

The concentration of the protective agent in the conductive paste may be in the range of 15% by mass concentration or less in the whole paste and is preferably in the range of 10% by mass concentration or less, when the concentration of the protective agent is too high, a necking phenomenon between the metal particles does not sufficiently occur during sintering and it is difficult to induce high conductivity.

(Solvent)

A solvent that can be used in the present Invention is not particularly limited and may be water and/or an organic solvent. In order to produce the conductive paste such that the conductive paste has a uniform particle system, the solvent used is preferably a good solvent that does not aggregate the metal micro-particles.

The solvent preferably volatilizes during the sintering of the conductive paste. However, high sintering temperature alters and damages a resin film. Thus, the solvent used is preferably an organic solvent having a boiling point in a temperature range in which the resin film is not damaged.

The concentration of the solvent in the conductive paste is not particularly limited and is preferably in the range of 60% by mass concentration or less.

(Preparation of Conductive Paste)

The conductive paste, according to the present invention, for pillar manufacturing can be provided with suitability as the conductive paste according to the present invention by adding a solvent easily used as a filling paste to the prepared metal micro-particles or by medium exchange.

A binder component such as resin, an anti-drying agent, a defoamer, an adhesion promoter for substrates, an oxidation inhibitor, various catalysts for promoting film production, various surfactants such as silicone surfactants and fluorinated surfactants, a leveling agent, a release accelerator, and the like can be added to the conductive paste, according to the present invention, for pillar manufacturing as aids as required unless an effect of the present invention is impaired.

A flux component may be added to the conductive paste according to the present invention unless an effect of the present invention is impaired. Adding the flux component enables the conductive paste to be used with further reducing power. The flux component used is not particularly limited and may be a general flux usually used. The flux component may contain rosin, an activator, a thixotropic agent, and the like that are usually used.

<Method for Manufacturing Conductive Pillars>

A preferred embodiment of a method for manufacturing conductive pillars according to the present invention is described below in detail with reference to drawings.

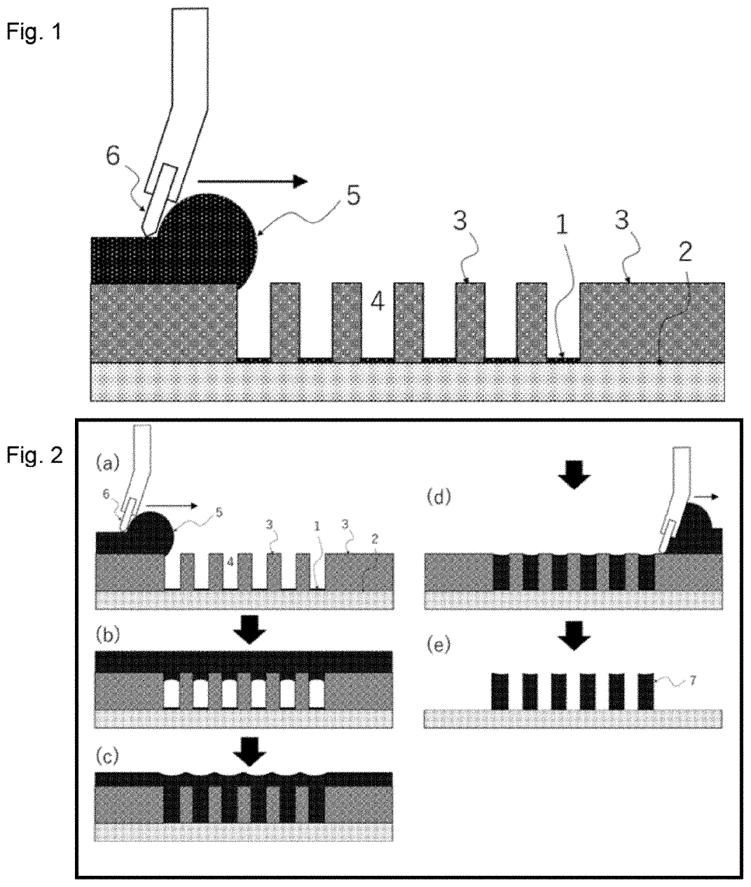

The method for manufacturing the conductive pillars according to the present invention includes a first step of applying, in an atmosphere with an atmospheric pressure of 10 kPa or less, the conductive paste to a surface of a resin film having an opening portion formed on a substrate having an electrode section, a second step of returning a pressure in the atmosphere to standard pressure after applying the conductive paste and filling the conductive paste in the opening portion, and a third step of removing the conductive paste remaining on the surface of the resin film. FIGS. 1 and 2 illustrate an embodiment of the method for manufacturing the conductive pillars according to the present invention.

(First Step)

The method for manufacturing the conductive pillars according to the present invention includes the first step of applying the conductive paste to the surface of the resin film having the opening pattern formed on the substrate having the electrode section in the atmosphere with an atmospheric pressure of 10 kPa or less.

In the present invention, if the conductive paste can be applied to the resin opening portion in the atmosphere with an atmospheric pressure of 10 kPa or less, an appropriate method can be used. For example, a rubber squeegee, a doctor blade, a dispenser, an ink jet, or the like can be used. In FIG. 1, a method in which the conductive paste is applied with a rubber squeegee is exemplified for reference.

The substrate having the electrode section is a substrate which has electrode pads 1 formed on a support 2 and a resin film 3 formed on a portion of the substrate that is other than the electrode pads 1 (FIG. 1). Incidentally, opening portions 4 are provided above the electrode pads 1.

Before the conductive paste is applied to the substrate, the pressure in an atmosphere around the substrate is reduced to an atmospheric pressure of 10 kPa or less. An appropriate method in which the atmospheric pressure around the substrate can be reduced to 10 kPa or less can be used. If the pressure is 10 kPa or less, the contamination of bubbles can be prevented when the pressure is returned to standard pressure. In an atmospheric pressure exceeding 10 kPa, air accumulates in the opening portions 4 to cause connection failure between electrodes when the substrate is bonded to a chip. This is not preferable.

After the atmospheric pressure is adjusted to 10 kPa or less, a squeegee 6 is moved in the direction of an arrow, that is, in parallel to the substrate, whereby a conductive paste 5 is applied to the surface of the resin film 3 (FIG. 1 and FIG. 2(a)). The film thickness on application is not particularly limited and an amount of the conductive paste 5 sufficient to manufacture pillars needs to be left. Thus, the conductive paste 5 is preferably applied to a film thickness larger than or equal to about one-half of the height of the pillars (FIG. 2(b)).

Material for the electrode pads is not particularly limited and may be, for example, aluminum, copper, nickel, gold, an aluminum-silicon-copper alloy, titanium, titanium nitride, tungsten, polysilicon, tantalum, tantalum nitride, a metal silicide, or a conductive material that is a combination of these. In order to ensure the adhesion of the surfaces of these metals to the conductive paste, various metals may be introduced as adhesion layers.

Material for the support is not particularly limited and nay be a publicly known one and those capable of forming the electrode pads, the resin layer, the conductive pillars, and the like on the support are not particularly limited. For example, silicon, glass, ceramic, resin, various metals, and the like can be exemplified and enumerated.

A publicly known technique can be used to prepare the resin film 3, which has the opening portions 4. A resin material used is not particularly limited as long as it is capable of making a cylindrical template form having a 20 to 30 μm opening portion. For example, photo-resist, polyimide, an epoxy resin, an epoxy molding compound (EMC), and various dry films can be used.

Material for the squeegee is not particularly limited. A squeegee made of plastic, rubber, or metal can be used. The thickness and length of the squeegee are not particularly limited. The pushing pressure during application is preferably such a pressure that does not damage an opening portion pattern of resin.

(Second Step)

The method for manufacturing the conductive pillars according to the present invention includes a second step of returning a pressure in the atmosphere to standard pressure after applying the conductive paste to fill the conductive paste in a resin opening portion. As shown in FIG. 2(c), the conductive paste on the resin film, which has the opening portions, is sucked into the opening portions, whereby the conductive paste is filled therein.

The standard pressure refers to a state of one atmosphere. The above step enables the conductive paste to be filled to the surfaces of the electrode pads without causing cavities, thereby enabling the occurrence of to be suppressed. The occurrence of the voids or the cavities inhibits the conductivity of the electrode pads from being ensured, thereby causing bonding failure.

(Third Step)

The method for manufacturing the conductive pillars according to the present invention includes a third step of removing the conductive paste remaining on the surface of the resin film. An appropriate method can be used as long as the conductive paste on the surface of the resin film can be removed. A blade or air pressure can be used or a method in which the conductive paste is polished off after drying or baking can be used. In FIG. 1(d), a method in which the conductive paste is removed with the squeegee is exemplified for reference.

The conductive paste remaining on the surface of the resin film possibly inhibits the peeling of resin. The remaining conductive paste may possibly cause short circuits between the pillars and therefore is not preferable.

(Method for Sintering Pillars)

When the conductive paste used is a thermosetting one, the pillars can be prepared in such a manner that the conductive paste prepared by the above method is heated to a temperature at which the metal micro-particles are necked.

A sintering method is not particularly limited. When material used is an oxidizable metal, photosintering is preferably performed or sintering is preferably performed in a forming gas containing hydrogen, a nitrogen atmosphere, or a reducing atmosphere containing formic acid or the like.

In the case of performing a sintering step, sintering is preferably performed in the range of 300° C. or lower in consideration of an influence on the resin film and the sintering time is preferably in the range of one minute to 60 minutes.

(About Step After Manufacturing Pillars)

In the case of removing the resin film (FIG. 2(e)), which is used in the present invention, a publicly known appropriate method can be used.

In the method for manufacturing the pillars according to the present invention, the resin film used may be a permanent film. In the case of using the permanent film, there is an advantage that a step of peeling the resin film can be eliminated.

Conductive pillars prepared by the method for manufacturing the pillars according to the present invention can be used to mount various electronic components and devices in, for example, flip-chip mounting.

### EXAMPLES

The present invention is described below in detail with reference to examples. Herein, “%” denotes “mass percent” unless otherwise specified.

(Preparation of Conductive Paste)

### <Synthesis of Metal Micro-Particles>

Nitrogen was injected into a mixture of copper (II) acetate monohydrate (3.00 g, 15.0 mmol) (produced by Tokyo Chemical Industry Co., Ltd.), ethyl 3-(3-(methoxy(polyethoxy)ethoxy)-2-hydroxypropylsulfanyl)propionate [an adduct of ethyl 3-mercaptopropionate to polyethylene glycol methylglycidyl ether (a polyethylene glycol chain with a molecular weight of 2,000 (91 carbon atoms)] (0.451 g) (produced by DIC Corporation), and ethylene glycol (10 mL) (produced by Kanto Chemical Co., Inc.) at a flow rate of 50 mL/min under heating. The mixture was degassed by two hours of stirring with aeration at 125° C. The mixture was returned to room temperature. A solution of hydrazine hydrate (1.50 g, 30.0 mmol) (produced by Tokyo Chemical Industry Co., Ltd.) diluted with 7 mL of water was slowly added dropwise to the mixture by using a syringe pump. About one-fourth of the amount of the solution was slowly added dropwise to the mixture over two hours and dropwise addition was stepped once, followed by stirring for two hours. After the suppression of foaming was confirmed, the residual amount of the solution was further added dropwise to the mixture over one hour. An obtained brown solution was heated to 60° C. and was further stirred for two hours, whereby a reduction reaction was terminated.

<Preparation of Aqueous Dispersion>

Subsequently, the reaction mixture was circulated in a hollow-fiber ultrafiltration membrane module (HIT-1-FUS1582, 145 cm², a molecular-weight cutoff of 150,000) manufactured by DAICEN MEMBRANE-SYSTEMS Ltd. in such a manner that the same amount of a 0.1% aqueous solution of hydrazine hydrate as an exuding filtrate was added to the reaction mixture until the amount of the filtrate exuding from the ultrafiltration membrane module reached about 500 mL, whereby the reaction mixture was purified. The supply of the 0.1% aqueous solution of hydrazine hydrate was stopped and the reaction mixture was concentrated by an ultrafiltration method, whereby an aqueous dispersion of a composite of copper micro-particles and 2.85 g of an organic compound containing thioether was obtained.

The obtained copper micro-particles were observed with a transmission electron microscope (TEM), whereby the primary particle size of the obtained copper micro-particles was found to be 20 nm. The content of nonvolatile matter in the aqueous dispersion was 16% by mass concentration. The weight loss measured by TG-DTA showed that 3% of an organic substance having a polyethylene oxide structure was present on the obtained copper micro-particles.

<Preparation of Conductive Paste>

In a 50 mL three-necked flask, 5 mL of the above aqueous dispersion was each sealed. Water was completely removed in such a manner that the flask was heated to 40° C. using a water bath and nitrogen was fed at a flow rate of 5 ml/min under reduced pressure, whereby 1.0 g of a dry powder of a copper micro-particle composite was obtained. Next, ethylene glycol bubbled with nitrogen for 30 minutes was added to the obtained dry powder in a globe bag purged with argon gas, followed by mixing for ten minutes in a mortar, whereby a conductive paste with a metal micro-particle content of 80% by mass concentration was prepared.

### Example 1

### <Substrate>

A substrate used for embedding was one having an opening portion pattern made on a stainless steel sheet (t=0.5 mm) by using a dry film resist with a thickness of 56 μm. Opening portions were column-shaped and had a depth of 56 μm. The diameters of the opening portions were 100 μm, 50 μm, 40 μm, 30 μm, and 20 μm. Thus, the aspect ratios thereof were 0.6, 1.1, 1.4, 1.9, and 2.8. The pattern was designed so as to have a hole-to-space ratio of 1:1.

<Application-Embedding Step>

An application-embedding step was performed in a globe box (MDB-1KPHYT manufactured by MIWA Mfg Co., Ltd.) by using an automatic grindmeter (manufactured by HOEI DEVICE Co., Ltd.). The automatic grindmeter, which was equipped with a rubber squeegee for screen printing, was installed in the globe box, which was filled with an argon gas. The substrate was adjusted so as to have a width of about 5 cm and was installed on a grind gauge portion of the automatic grindmeter. The prepared conductive paste was put on the installed substrate and the pressure in the globe box was reduced to 3 kPa. After the pressure reached 3 kPa, the conductive paste was immediately applied to the substrate by using the automatic grindmeter. The coating speed was about 3 cm/s.

After the completion of application, the pressure was immediately returned to standard pressure by using an argon gas such that the conductive paste was not dried.

<Remova1 Step>

After returning the pressure to standard pressure, an excess of the conductive paste remaining on the surface of resist was removed using again the rubber squeegee attached to the automatic grindmeter.

<Sintering Step>

A sintering step of this example was performed in an argon atmosphere by using a hotplate. The obtained substrate was baked at 120° C. for five minutes and was then sintered at 250° C. for ten minutes. In this example, no resist was peeled after sintering.

### Example 2

### <Substrate>

A substrate used for embedding was one having an opening portion pattern made on a silicon wafer (t=775 μm) by using a photoresist (SU-8). Opening portions were column-shaped and had a depth (resist thickness) of about 50 μm. The diameters of the opening portions were 100 μm, 50 μm, 40 μm, 30 μm, and 20 μm. Thus, the aspect ratios thereof were about 0.5 1.0, 1.3, 1.6, and 2.5. The pattern was designed sc as to have a hole-to-space ratio of 1:1.

<Application-Embedding Step>

An application-embedding step was performed in the globe box by using the automatic grindmeter in the same manner as in Example 1. The automatic grindmeter, which was equipped with a rubber squeegee for screen printing, was installed in the globe box, which was filled with an argon gas. The substrate was adjusted so as to have a width of about 5 cm and was installed on the grind gauge portion of the automatic grindmeter. The prepared conductive paste was put on the installed substrate and the pressure in the globe box was reduced to 3 kPa. After the pressure reached 3 kPa, tho conductive pasta was immediately applied to tho substrata by using the automatic grindmeter. The coating speed was about 3 cm/s.

After the completion of application, the pressure was immediately returned to standard pressure by using an argon gas such that the conductive paste was not dried.

<Removal Step>

After returning the pressure to standard pressure, an excess of the conductive paste remaining on the surface of resist was removed using again the rubber squeegee attached to the automatic grindmeter in the same manner as in Example 1.

<Sintering Step>

A sintering step of this example was performed in the argon atmosphere by using the hotplate in the same manner as in Example 1. The obtained substrate was baked at 120° C. for five minutes and was then sintered at 250° C. for ten minutes. In this example, no resist was peeled after sintering.

### Comparative Example 1

### <Substrate>

A substrate used in this comparative example was the same as that used in Example 1. The substrate, which was used for embedding, was one having an opening portion pattern made on a stainless steel sheet (t=0.5 mm) by using a dry film resist with a thickness of 56 μm. Opening portions were column-shafted and had a depth of 56 μm. The diameters of the opening portions were 100 μm, 50 μm, 40 μm, 30 μm, and 20 μm.

<Application-Embedding Step>

An application-embedding step was performed in a globe box by using an automatic grindmeter. The automatic grindmeter, which was equipped with a rubber squeegee for screen printing, was installed in the globe box, which was filled with an argon gas such that the pressure in the globe box is standard pressure. The substrate was adjusted so as to have a width of about 5 cm and was installed on a grind gauge portion of the automatic grindmeter. The prepared conductive paste was put on the installed substrate and the conductive paste was immediately applied to the substrate by using the automatic grindmeter. The coating speed was about 3 cm/s.

<Removal Step>

An excess of the conductive paste remaining on the surface of resist was removed using again the rubber squeegee attached to the automatic grindmeter.

<Sintering Step>

A sintering step of this comparative example was performed in the argon atmosphere by using the hotplate in the same manner as in Example 1. The obtained substrate was baked at 120° C. for five minutes and was then sintered at 250° C. for ten minutes. In this comparative example, no resist was peeled after sintering.

(Evaluation-Observation)

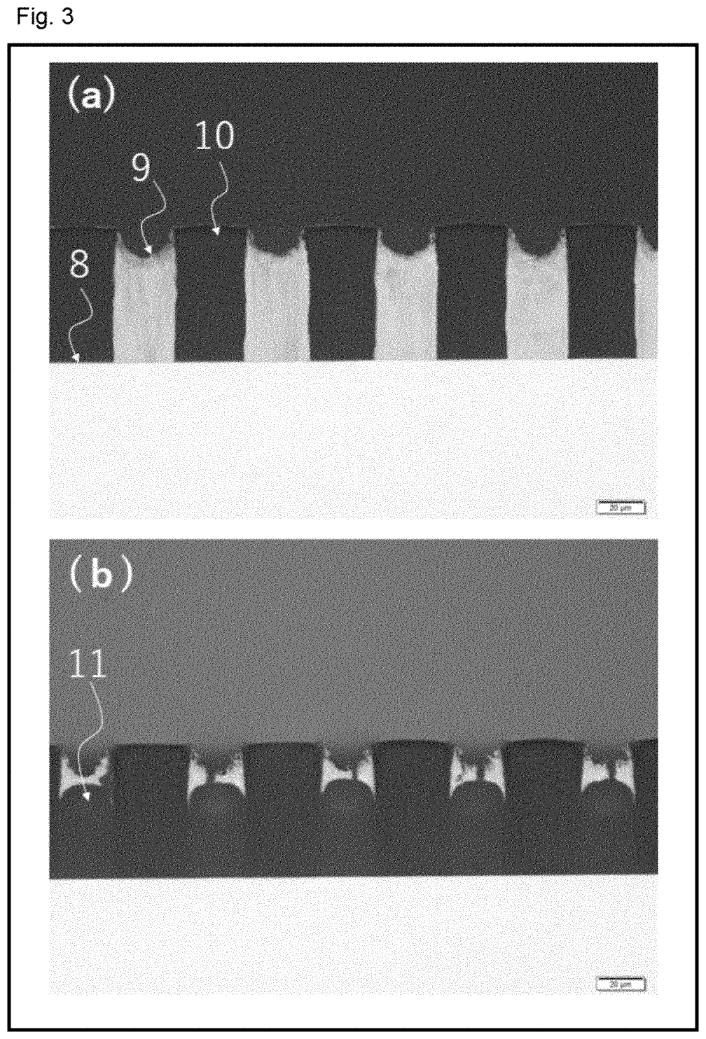

The filling state of the conductive paste in each opening portion was evaluated. The conductive paste was filled in the opening portion and each sintered substrate was cut into an about 1 cm small piece, which was embedded in resin. The embedded small piece was cut such that a section thereof was exposed, followed by observation and evaluation by using an optical microscope. FIG. 3 shows the filling state of the conductive paste in the opening portions of the substrate that was obtained after the conductive paste was filled in the opening portions, which had a diameter of 30 μm, and was sintered. FIG. 3(a) shows results of Example 1 and FIG. 3(b) shows results of Comparative Example 1.

Referring to FIG. 3(a), it is clear that the conductive paste 9 is densely filled up to an upper portion of a SUS substrate 8 that is a support. Furthermore, it is clear that the conductive paste is uniformly filled in all of the opening portions shown in the figure. On the other hand, in FIG. 3(b), although the conductive paste was observed on the surface of resist 10, the conductive paste was not filled up to an interface of a SUS substrate and cavities 11 were observed. Furthermore, in (b), cracks probably due to the volume expansion of air by sintering were observed.

TABLE 1

| | | Paste filling factor [%] | | |
|---|---|---|---|---|
| | | | | Comparative |
| | | Example 1 | Example 2 | Example 1 |
| Diameter | 100 | 65% | 66% | 65% |
| of opening | 50 | 74% | 73% | 37% |
| portion | 40 | 72% | 71% | 25% |
| [μm] | 30 | 74% | 72% | 25% |
| | 20 | 78% | 79% | 34% |

Table 1 shows the filling factor of the conductive paste that was roughly estimated from a section of the sample prepared in each of the examples and the cooperative example. The filling factor represents the percentage when the volume of a resist opening portion is 100. Interparticle gaps (1 μm or less) capable of being confirmed with an electron microscope wore calculated on the assumption that the interparticle gaps were filled with particles.

It became clear that using a method for manufacturing a pillar according to the present invention enabled a filling factor of 70% or more to be ensured when the diameter of an opening portion was 50 μm or less. This result shows that a conductive pillar that is difficult to prepare at standard pressure without optimizing the type of a leveling agent or a solvent can be readily prepared.

### REFERENCE SIGNS LIST

1 Electrode pad

2 Support

3 Resin (resist or the like)

4 Opening portion

5 conductive paste

6 Squeegee

7 Conductive pillar

8 Support (made of SUS)

9 Copper paste

10 Resist

11 Cavity

1. A method for manufacturing a conductive pillar on a substrate having an electrode section by using a conductive paste containing metal micro-particles, the method comprising:
a first step of applying, in an atmosphere with an atmospheric pressure of 10 kPa or less, the conductive paste to a surface of a resin film having an opening portion formed on the substrate having the electrode section;
a second step of returning a pressure in the atmosphere to standard pressure after applying the conductive paste and filling the conductive paste in the opening portion; and
a third step of removing the conductive paste remaining on the surface of the resin film.

2. The method for manufacturing the conductive pillar according to claim 1, wherein a squeegee made of rubber or metal is used in the step of applying the conductive paste and the step of removing the conductive paste.

3. The method for manufacturing the conductive pillar according to claim 1, wherein the step of applying the conductive paste is performed by screen printing.

4. The method for manufacturing the conductive pillar according to claim 1, wherein the opening portion formed on the substrate having the electrode section has a diameter of 50 μm or less.
